(19) United States
(12) Patent Application Publication
(10) Pub. No.: US 2022/0011899 A1
(43) Pub. Date: Jan. 13, 2022

(54) TOUCH SENSING METHOD AND ELECTRONIC DEVICE INCLUDING TOUCH SENSING DEVICE

(71) Applicant: SAMSUNG ELECTRO-MECHANICS CO., LTD., Suwon-si (KR)

(72) Inventors: Min Keun KIM, Suwon-si (KR); Ho Kwon YOON, Suwon-si (KR); Bang Chul KO, Suwon-si (KR); Joo Yul KO, Suwon-si (KR)

(73) Assignee: SAMSUNG ELECTRO-MECHANICS CO., LTD., Suwon-si (KR)

(21) Appl. No.: 17/030,762

(22) Filed: Sep. 24, 2020

(30) Foreign Application Priority Data
Jul. 7, 2020 (KR) 10-2020-0083287

(51) Int. Cl. G06F 3/041; G06F 3/044; G06F 3/0488

(52) U.S. Cl. CPC G06F 3/0418; G06F 3/0488; G06F 3/0447

(57) ABSTRACT

A touch sensing method includes: generating respective oscillation signals having a resonant frequency, the respective oscillation signals being changeable according to a plurality of touch inputs applied to a first touch switch unit and a second touch switch unit, formed in a housing of an electronic device; analyzing the applied plurality of touch inputs, based on a change in the resonant frequency of the generated oscillation signals; and discerning and sensing a type of a touch operation according to a pattern of the plurality of touch inputs, based on results of the analyzing of the applied plurality of touch inputs.

### CROSS-REFERENCE TO RELATED APPLICATIONS

This application claims the benefit under 35 U.S.C. § 119(a) of Korean Patent Application No. 10-2020-0083287 filed on Jul. 7, 2020 in the Korean Intellectual Property Office, the entire disclosure of which is incorporated herein by reference for all purposes.

### BACKGROUND

### 1. Field

The following description relates to a touch sensing method and an electronic device including a touch sensing device.

### 2. Description of Related Art

In general, wearable devices have become thinner, simpler and have been implemented with sleeker, more elegant designs. Thus, existing mechanical switches are being eliminated, along with the implementation of dustproof and waterproof technologies, as well as the development of an integrated model with a smooth design.

Currently, technologies such as touch on metal (ToM) technology that implements touch inputs on metal, capacitor sensing technology using touch panels, micro-electro-mechanical-system (MEMS), and micro strain gauges are being developed. Furthermore, a force touch function is also being developed.

In the case of an existing mechanical switch, a large size of the mechanical switch and a large internal space are required to implement the function(s) of the switch. Thus, there may be a disadvantage that the exterior of the wearable device may not be sleek or elegant due to a shape protruding to the outside of an external case or the structure not being integrated with the external case, and the wearable device may occupy a relatively large space.

In addition, there is a risk of electric shocks due to direct contact with a mechanical switch that is electrically connected and, in particular, there is a disadvantage that it may be difficult to obtain a waterproof and dustproof construction of the wearable device due to structural characteristics of the mechanical switch.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In one general aspect, a touch sensing method includes: generating respective oscillation signals having a resonant frequency, the respective oscillation signals being changeable according to a plurality of touch inputs applied to a first touch switch unit and a second touch switch unit, formed in a housing of an electronic device; analyzing the applied plurality of touch inputs, based on a change in the resonant frequency of the generated oscillation signals; and discerning and sensing a type of a touch operation according to a pattern of the plurality of touch inputs, based on results of the analyzing of the applied plurality of touch inputs.

The touch sensing method may further include: determining a touch input level according to a strength of the plurality of touch inputs, based on the analyzed results; and calculating an operation output value of the electronic device according to the determined touch input level.

The calculating of the operation output value of the electronic device according to the determined touch input level may include: calculating either one of a volume, a vibration strength, an operation time period, a number of operations, or an operation frequency of the electronic device to match the touch input level.

The discerning and sensing of the type of the touch operation may include comparing any one or any combination of any two or more of a number of touch inputs, locations of touch inputs, a progress direction of the touch operation, and a touch strength level, with respect to the plurality of touch inputs, to discern the type of the touch operation.

The analyzing of the applied plurality of touch inputs may include collecting and analyzing only a plurality of pieces of touch input data applied within a reference time period previously stored in the electronic device.

The discerning and sensing of the type of the touch operation may include: determining whether the collected plurality of pieces of touch input data corresponds to a touch input applied to the first touch switch unit and a touch input applied to the second touch switch unit; and discerning the type of the touch operation as any one of a multiple touch, a sequential multiple touch, a multiple slide touch, a multiple swipe touch, and a squeeze, in response to a result of the determining whether the collected plurality of pieces of touch input data corresponds to the touch input applied to the first touch switch unit and the touch input applied to the second touch switch unit being that the collected plurality of pieces of touch input data corresponds to the touch input applied to both the first touch switch unit and the touch input applied to the second touch switch unit.

The touch sensing method may further include: discerning the type of the touch operation as any one of a multiple touch, a slide touch, and a swipe touch with respect to a single touch switch unit among the first and second touch switch units, in response to the result of the determining whether the collected plurality of pieces of touch input data corresponds to the touch input applied to the first touch switch unit and the touch input applied to the second touch switch unit being that the collected plurality of pieces of touch input data does not correspond to the touch input applied to both the first touch switch unit and the touch input applied to the second touch switch unit.

The touch sensing method may further include: determining the number of data of touch inputs first applied, among the collected plurality of pieces of touch input data; and further discerning the type of the touch operation as the sequential multiple touch, in response to the result of the determining whether the collected plurality of pieces of touch input data corresponds to the touch input applied to the first touch switch unit and the touch input applied to the second touch switch unit being that the collected plurality of pieces of touch input data corresponds to the touch input applied to both the first touch switch unit and the touch input applied to the second touch switch unit, and the number of data of touch inputs first applied being one.

The touch sensing method may further include: determining whether each of the plurality of touch inputs first applied is sustained for a minimum time period while having a strength level greater than or equal to a predetermined reference strength level; and further discerning the type of the touch operation as the squeeze, in response to the result of the determining whether the collected plurality of pieces of touch input data corresponds to the touch input applied to the first touch switch unit and the touch input applied to the second touch switch unit being that the collected plurality of pieces of touch input data corresponds to the touch input applied to both the first touch switch unit and the touch input applied to the second touch switch unit, the number of data of the touch inputs first applied being a plural number, and a result of the determining of whether each of the plurality of touch inputs first applied is sustained for the minimum time period while having the strength level greater than or equal to the predetermined reference strength level is that the plurality of touch inputs first applied are sustained for the minimum time period while having the strength level greater than or equal to the predetermined reference strength level.

The discerning and sensing of the type of the touch operation may include comparing a position of a first applied touch input, among the collected plurality of pieces of touch input data, with a position of a second applied touch input, among the collected plurality of pieces of touch input data, to determine a progress direction of the touch operation.

The discerning and sensing of the type of the touch operation may include: determining strength levels of the collected plurality of pieces of touch input data, respectively; and discerning the type of the touch operation as a swipe touch, in response to a result of the determining of the strength levels of the collected plurality of pieces of touch input data being that the strength levels of the collected plurality of pieces of touch input data sequentially decrease.

The touch sensing method may further include: discerning the type of the touch operation as a slide touch, in response to a result of the determining of the strength levels of the collected plurality of pieces of touch input data being that the strength levels of the collected plurality of pieces of touch input data are maintained constant or increase.

In another general aspect, an electronic device includes: a touch switch unit formed in a housing; and a touch sensing device configured to sense a touch input applied to the touch switch unit, wherein the touch switch unit includes: a first touch switch unit disposed on one side surface of the electronic device; and a second touch switch unit disposed on another side surface of the electronic device.

The touch sensing device may include: an oscillation circuit configured to generate respective oscillation signals corresponding to the first touch switch unit and the second touch switch unit, each of the respective oscillation signals having a resonant frequency that is changeable according to a plurality of touch inputs, constituting the touch input, applied to the first touch switch unit and the second touch switch unit; and a detection circuit configured to discern a type of a touch operation according to a pattern of the plurality of touch inputs, based on a change in resonant frequency of the generated respective oscillation signals.

The detection circuit may be further configured to determine a touch input level according to a strength of the plurality of touch inputs, and calculate an operation output value of the electronic device according to the determined touch input level.

The detection circuit may be further configured to compare any one or any combination of any two or more of a number of touch inputs, locations of touch inputs, a progress direction of the touch operation, and a touch strength level, with respect to the plurality of touch inputs, to discern the type of the touch operation.

The touch sensing device may further include: an inductor element configured to exhibit a change in inductance as the touch input is applied to the touch switch unit; and a capacitor element electrically connected to the inductor element, and configured to exhibit a change in capacitance as the touch input is applied to the touch switch unit. The oscillation circuit may be electrically connected to the inductor element and the capacitor element, to generate the respective oscillation signals.

Each of the first touch switch unit and the second touch switch unit may include a plurality of touch members. The touch sensing device may further include: a plurality of inductor elements corresponding to the plurality of touch members and configured to exhibit a change in inductance as the plurality of touch inputs are applied to the first touch switch unit and the second touch switch unit; and a plurality of capacitor elements respectively electrically connected to the plurality of inductor elements and configured to exhibit a change in capacitance as the plurality of touch inputs are applied to the first touch switch unit and the second touch switch unit. The detection circuit may be further configured to analyze only a plurality of pieces of touch input data applied within a reference time period previously stored, among the plurality of touch inputs, to discern the type of the touch operation.

The first touch switch unit and the second touch switch unit may be symmetrically disposed on the one side surface of the electronic device and the other side surface of the electronic device. Each of the first touch switch unit and the second touch switch unit may include a plurality of touch members. A dividing line or a dividing surface may not be formed between the plurality of touch members.

The touch switch unit may be disposed in a region of a dashboard of a vehicle including a steering wheel and a center fascia. The electronic device may be configured to determine a touch input level according to a strength of the touch input applied to the touch switch unit, and calculate an operating output value implemented in the vehicle differently according to the determined touch input level.

In another general aspect, an electronic device includes: a first group of touch members disposed on one surface of the electronic device; a second group of touch members disposed on another surface of the electronic device; an oscillation circuit configured to generate a first group of oscillation signals corresponding to the first group of touch members, and a second group of oscillation signals corresponding to the second group of touch members; and a controller configured to determine a type of a touch operation corresponding to a pattern of a plurality of touch inputs applied to a plurality touch members among the first group of touch members and the second group of touch members, based on a detected change in resonant frequency of one or more oscillation signals among the first group of oscillation signals and the second group of oscillation signals.

The controller may be further configured to determine an operation output value of the electronic device based on a strength of the plurality of touch inputs.

The controller may be further configured to compare any one or any combination of any two or more of a number of the plurality of touch inputs, locations of the plurality of touch inputs, a progress direction of the plurality of touch inputs, and a touch strength level of the plurality of touch inputs, to determine the type of the touch operation.

The controller may be further configured to determine the type of the touch operation based on whether a strength of the plurality of touch inputs is above a reference strength level for a predetermined amount of time.

Other features and aspects will be apparent from the following detailed description, the drawings, and the claims.

### BRIEF DESCRIPTION OF DRAWINGS

FIG. 1 is an example view of an exterior of an electronic device, according to an embodiment.

FIG. 2 is an example partially enlarged view of one side surface of the electronic device of FIG. 1.

FIG. 3 is an example view of a cross-sectional structure (a Y-Z cross-section) of one side surface of the electronic device of FIG. 1.

FIG. 4 is an example view of a cross-sectional structure (an X-Z cross-section) of one side surface of the electronic device of FIG. 1.

FIG. 5 is another example view of a cross-sectional structure (an X-Z cross-section) of one side surface of the electronic device of FIG. 1.

FIG. 6 is an example view of an operation description in which an electronic device, according to an embodiment, adjusts an output according to a strength level of a touch input.

FIG. 7 is an example view illustrating respective cross-sectional structures (X-Z cross-sections) of both side surfaces of the electronic device of FIG. 1, and connection structures to the side surfaces.

FIG. 8 is an example view illustrating an operation of discerning and sensing a type of a touch input, when the touch input is applied to a touch switch unit on one side of an electronic device, according to an embodiment.

FIG. 9 is an example view illustrating an operation of discerning and sensing a type of a touch input, when the touch input is applied to touch switch units on both sides of an electronic device, according to an embodiment.

FIG. 10 is an example view schematically illustrating a change in frequency or inductance of oscillation signals generated in a plurality of touch members by a slide touch input, according to an embodiment.

FIG. 11 is an example view schematically illustrating a change in frequency or inductance of oscillation signals generated in a plurality of touch members by a swipe touch input, according to an embodiment.

FIG. 12 is an example view schematically illustrating a change in frequency or inductance of an oscillation signal generated in a plurality of touch members by a squeeze touch input, according to an embodiment.

FIG. 13 is a schematic diagram of a controller in communication with an oscillation circuit, according to an embodiment.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Herein, it is noted that use of the term “may” with respect to an embodiment or example, e.g., as to what an embodiment or example may include or implement, means that at least one embodiment or example exists in which such a feature is included or implemented while all examples and examples are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as illustrated in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes illustrated in the drawings may occur. Thus, the examples described herein are not limited to the specific shapes illustrated in the drawings, but include changes in shape that occur during manufacturing.

The features of the examples described herein may be combined in various ways as will be apparent after gaining an understanding of the disclosure of this application. Further, although the examples described herein have a variety of configurations, other configurations are possible as will be apparent after an understanding of the disclosure of this application.

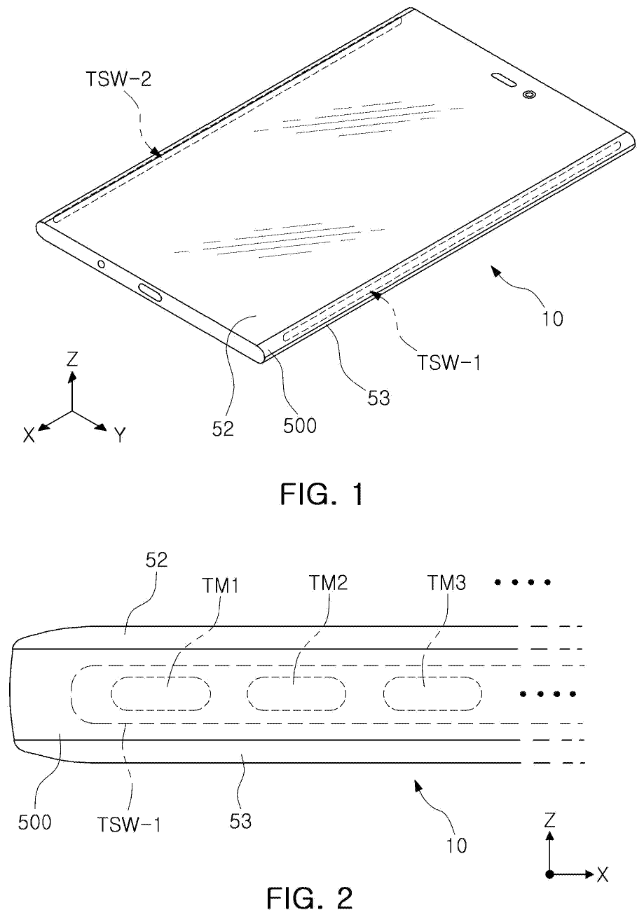

FIG. 1 is an example view of an exterior of an electronic device 10, according to an embodiment.

Referring to FIG. 1, the electronic device 10 may include, for example, a front display glass 52, a rear cover53, and a housing 500.

The front display glass 52 may be disposed on one surface of the electronic device 10, and the rear cover 53 may be disposed on the other surface of the electronic device 10.

The housing 500 may be an external case exposed to an external space around the electronic device 10. For example, in an example in which the electronic device 10 is a mobile device, the housing 500 may be a cover disposed on a side (a side surface) of the mobile device. For example, the housing 500 may be integrally formed with the rear cover 53, which may be disposed on a rear surface of the electronic device 10, or may be formed separately from the rear cover 53.

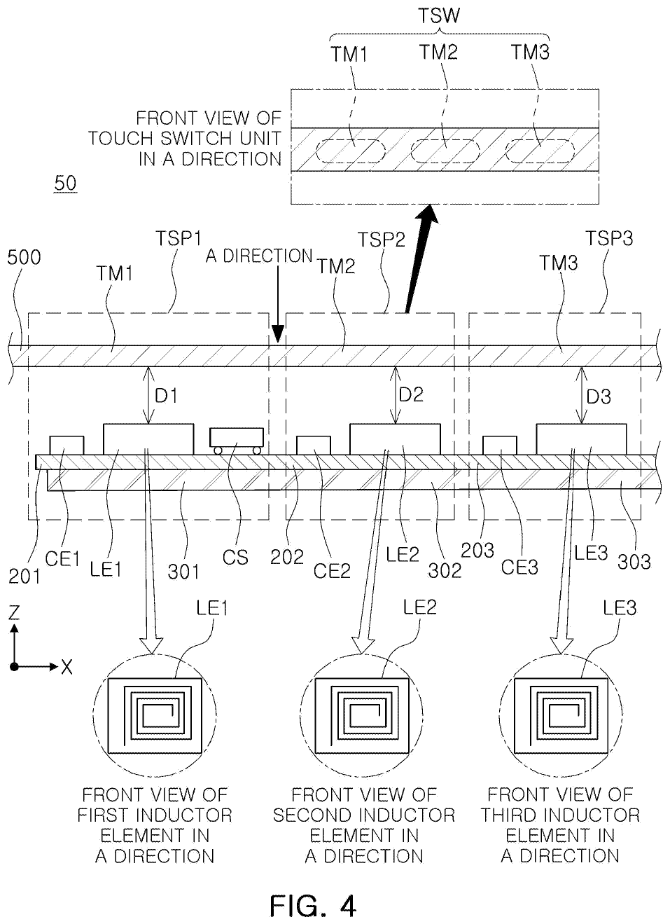

The electronic device 10 may include first and second touch switch units TSW-1 and TSW-2. The touch switch units may be disposed on the housing 500, but are not limited to such a configuration. A touch sensing device 50 (FIG. 4) configured to sense external pressures applied to the first and second touch switch units TSW-1 and TSW-2 may be disposed inside the housing of the electronic device 10.

The touch switch unit TSW may be disposed on a cover of the electronic device 10. In this case, the cover on which the touch switch unit TSW is disposed may be a cover except for the front display, for example, a side cover, the rear cover 53, or a cover that may be formed on a portion of the front surface. For convenience of description, as an example, the switch unit TSW will be described herein as being disposed on the housing 500, which is a side cover (the side surface) of the electronic device 10. However, the disclosure is not limited to this example.

Referring to FIG. 1, the touch switch unit TSW may include, for example, a first touch switch unit TSW-1 disposed on one side surface of the electronic device 10, and a second touch switch unit TSW-2 disposed on the other side surface of the electronic device 10. In addition, each of the first touch switch unit TSW-1 and the second touch switch unit TSW-2 may be formed integrally with the housing 500, and may be a touch region including a plurality of touch members for sensing a touch applied with force.

For reference, in this specification, a touch, a touch input, and a touch application may all include a contact touch contacting external surfaces of the plurality of touch members (illustrated in FIG. 2) without power, and a force touch involving force pressing with power (pressure).

Therefore, a “touch” in this disclosure may be understood to include either one of contact and force.

Referring to FIG. 1, the electronic device 10 may be a portable device such as a smartphone or the like, and may be a wearable device such as a smartwatch, but is not limited to a specific device. The electronic device 10 may be an electronic device that may be portable or worn, or an electronic device having a switch for controlling an operation.

For example, the electronic device 10 may include a smartphone, a personal digital assistant, a digital video camera, a digital still camera, a network system, a personal computer, a monitor, a tablet computer, a laptop computer, a netbook, a television, a video game, a smartwatch, an automotive device, or the like, but is not limited to these examples.

In a case of an electronic device such as a general mobile phone, a volume button or a power button may be formed on a side surface of the electronic device as a physical button (key). In this case, the physical button may protrude toward an external space to be pressed with a user's hand. When using the physical button, there may be a limitation to durability due to a cause of wear and the like, and there may be a limitation to waterproofing.

Embodiments of a touch sensing device and an electronic device, which are proposed to solve the aforementioned limitations, will be described with reference to FIGS. 2 to 12.

For each of the drawings of the present disclosure, unnecessary duplicate descriptions will be omitted for the same reference numerals and components having the same function, and possible differences for each of the drawings may be described.

FIG. 2 is an example partially enlarged view of one side surface of the electronic device 10.

Referring to FIG. 2, for example, one side surface of the electronic device 10 may include the housing 500 corresponding to a side cover, and the first touch switch unit TSW-1 may be provided in at least a portion of the housing 500. The housing 500 and the second touch switch unit TSW-2 may be provided on the other side surface of the electronic device 10, and a description of the first touch switch unit TSW-1 applies equally to the second touch switch unit TSW-2.

A plurality of touch members may be included in the first touch switch unit TSW-1. For example, as illustrated in FIG. 2, the plurality of touch members, such as a first touch member TM1, a second touch member TM2, and a third touch member TM3, may be arranged to be parallel to a surface of the first touch switch unit TSW-1. A shape of each of the touch members and an arrangement structure of the plurality of touch members TM1, TM2, and TM3 may be varied, and FIG. 2 is merely an example of an arrangement structure of the plurality of touch members.

Also, a dividing line or a dividing surface may not be provided between the plurality of touch members TM1, TM2, and TM3 included in the first touch switch unit TSW-1. Therefore, both of the side surfaces of the electronic device 10 may have a smooth integral exterior. Then, a portion of force may be transferred to another touch member according to strength of the force touch applied to each of the touch members. Therefore, a continuous touch input may be applied across a plurality of touch members by a user's swipe or slide operation.

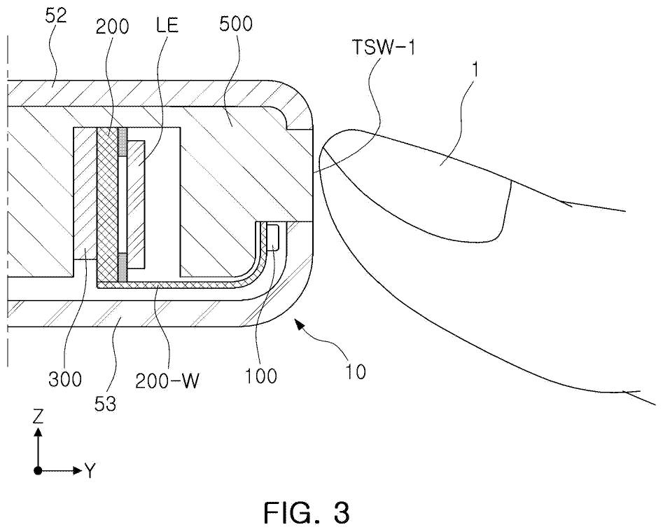

FIG. 3 is an example view of a cross-sectional structure (a Y-Z cross-section) of one side surface of the electronic device 10.

Referring to FIG. 3, a basic concept of the disclosure herein may be to sense a degree of bending of the housing 500 when a pressure is applied to the first touch switch unit TSW-1 by a user hand 1, to enable a force touch input without a physical button on the side surface of the electronic device 10.

As described with reference to FIG. 1, the electronic device 10 may have the housing 500, such as a metal frame, in a central portion thereof, the front display glass 52 in an upper portion thereof, and the rear cover 53 in a lower portion thereof.

For example, referring to FIG. 3, the electronic device 10 may include the housing 500, and the housing 500 may include the first touch switch unit TSW-1 in at least a region thereof.

In addition, the electronic device 10 may include the touch sensing device 50 (illustrated in FIG. 4), and the touch sensing device may be inserted into and disposed inside the housing 500. The touch sensing device 50 may sense an external pressure applied to the first touch switch unit TSW-1.

The touch sensing device 50 may be a device capable of detecting a force touch input by inductive sensing. More specifically, referring to FIG. 3, force may be applied to the first touch switch unit TSW-1 by a user's hand 1. Therefore, the housing 500 may be inwardly bent around the position of the first touch switch unit TSW-1 by the force, and a change in size of an air gap formed by an inductor element LE of the touch sensing device 50 and the housing 500 may be caused.

In this case, when the size of the air gap changes, a change in inductance may occur. Therefore, when a change in inductance of a reference value or higher is sensed, the touch sensing device 50 may detect that a touch input by force is applied to the first touch switch unit TSW-1.

Referring to FIG. 3, a touch sensing device 50 and the electronic device 10 may include, for example, an inductor element LE, a substrate 200, and a bracket 300, to sense a force touch input. In addition, the touch sensing device 50 and the electronic device 10 may further include a connecting conductor 200-W and a sensing electrode 100, to sense a contact touch input.

According to an embodiment, a touch input applied to the first touch switch unit TSW-1 by the user may include a contact touch and a force touch. For example, a touch input by contact may be sensed by a change in capacitance occurring in the housing 500 or the rear cover 53, when a user's hand 1 approaches the first touch switch unit TSW-1. As described above, when it is determined that the user applies a touch to the first touch switch unit TSW-1, as described above, a touch input by force may be sensed by a change in inductance caused due to a decrease in a distance between the housing 500 and the inductor element LE.

For example, the electronic device 10 may be configured such that whether a touch applied to the one side surface of the electronic device 10 by a user's hand 1 is an intended contact touch is determined by measuring an amount of change in capacitance, and force strength of the touch is then determined by measuring an amount of change in inductance.

The connecting conductor 200-W may be a conductor wire or a conductor line using a flexible PCB, and is not limited to the illustrated form of the drawings. Further, the sensing electrode 100 may be connected to at least one of both electrodes of the inductor element LE or a capacitor element (not illustrated) through the connecting conductor 200-W.

FIG. 4 is an example view of a cross-sectional structure (an X-Z cross-section) of one side surface of the electronic device of FIG. 1.

Referring to FIG. 4, the electronic device 10 may include a touch sensing unit including a first touch sensing part TSP1, a second touch sensing part TSP2, and a third touch sensing part TSP3. For reference, FIG. 4 illustrates an embodiment in which three touch members (the first, second, and third touch members TM1, TM2, and TM3) and the touch sensing unit (the first touch sensing part TSP1, the second touch sensing part TSP2, and the third touch sensing part TSP3) are provided, but this example is merely illustrative. For example, the first touch switch unit TSW-1 provided on the one side surface of the electronic device 10 may include at least one touch member and touch sensing unit. In addition, as described above, since a description related to the first touch switch unit TSW-1 may be applied to the second touch switch unit TSW-2, the second touch switch unit TSW-2 may be include at least one touch member and touch sensing unit.

Referring to FIG. 4, the first touch sensing part TSP1 may include the first touch member TM1 formed in the housing 500, a first inductor element LE1 disposed inside the first touch member TM1, opposing and spaced apart from the first touch member TM1 by a predetermined distance (e.g., D1), and having inductance changeable upon force touch through the first touch member TM1, and a first capacitor element CE1 connected to the first inductor element LE1 in parallel, series, or series-parallel. In addition, the first touch sensing part TSP1 may further include a circuit unit CS (e.g., an IC. The circuit unit CS may generate a first oscillation signal having a resonant frequency that is changeable based on the first inductor element LE1, and may recognize a first touch input based on the resonant frequency of the first oscillation signal.

For reference, FIG. 4 illustrates an example in which the circuit unit CS is included in the first touch sensing part TSP1, but this example is merely illustrative. For example, according to the arrangement relationship with other components of the present disclosure, such as the substrate 200 and the bracket 300, the circuit unit CS may be included in other touch sensing parts such as the second touch sensing part TSP2, the third touch sensing part TSP3, or the like. In addition, a separate circuit unit CS may be included in each of the first, second, and third touch sensing parts TSP1, TPS2, and TSP3.

The second touch sensing part TSP2 may include the second touch member TM2 formed in the housing 500, a second inductor element LE2 disposed inside the second touch member TM2, opposing and spaced apart from the second touch member TM2 by a predetermined distance (e.g., D2), and having inductance changeable upon force touch through the second touch member TM2, and a second capacitor element CE2 connected to the second inductor element LE2 in parallel, series, or series-parallel. In addition, the circuit unit CS may be electrically connected to the second inductor element LE2, to generate a second oscillation signal having a resonant frequency that is changeable based on the second inductor element LE2, and may recognize a second touch input based on the resonant frequency of the second oscillation signal.

The third touch sensing part TSP3 may include a third touch member TM3 formed in the housing 500, a third inductor element LE3 disposed inside the third touch member TM3, opposing and spaced apart from the third touch member TM3 by a predetermined distance (e.g., D3), and having inductance changeable upon force touch through the third touch member TM3, and a third capacitor element CE3 connected to the third inductor element LE3 in parallel, series, or series-parallel. In addition, the circuit unit CS may be electrically connected to the third inductor element LE3, to generate a third oscillation signal having a resonant frequency that is changeable based on the third inductor element LE3, and may recognize a third touch input based on the resonant frequency of the third oscillation signal.

The predetermined distance (e.g., D1) between the first touch member TM1 and the first inductor element LE1 may be designed to be equal to the predetermined distance (e.g., D2) between the second touch member TM2 and the second inductor element LE2 and the predetermined distance (e.g., D3) between the third touch member TM3 and the third inductor element LE3, and may be different from each other in practice.

The touch sensing device 50 may include a substrate 200 and a bracket 300.

The first inductor element LE1, the second inductor element LE2, the third inductor element LE3, and the circuit unit CS may be mounted on the substrate 200. For example, the substrate 200 may include a first substrate 201 for mounting the first inductor element LE1, a second substrate 202 for mounting the second inductor element LE2, and a third substrate 203 for mounting the third inductor element LE3.

The bracket 300 may support the substrate 200 to maintain the predetermined distance D1 between the first inductor element LE1 and the first touch member TM1, the predetermined distance D2 between the second inductor element LE2 and the second touch member TM2, and the predetermined distance D3 between the third inductor element LE3 and the third touch member TM3. For example, the bracket 300 may include a first bracket 301 for supporting the first substrate 201, a second bracket 302 for supporting the second substrate 202, and a third bracket 303 for supporting the third substrate 203.

Referring to the first touch sensing part TSP1 illustrated in FIG. 4, the first inductor element LE1 may be spaced apart from an internal side surface of the first touch member TM1 by the predetermined distance D1 and may be mounted on one surface of the first substrate 201, and the first capacitor element CE1 and the circuit unit CS (e.g., IC) may be mounted on the one surface of the first substrate 201. The first bracket 301 may be attached to the other surface of the first substrate 201.

The first bracket 301 may be a conductor such as metal, but is not limited to metal. The first bracket 301 may be attached to an internal structure of the electronic device 10 to which the touch sensing device 50 is applied, or may be supported using a separate support member. The first bracket 301 is not limited to a specific structure, as long as the first inductor element LE1 and the first touch member TM1 maintain the predetermined distance D1.

In addition, the circuit unit CS (e.g., IC), the first inductor element LE1, and the second capacitor element CE1 may be arranged on the one surface of the first substrate 201, and the circuit unit CS (e.g., IC), the first inductor element LE1, and the first capacitor element CE1 may be electrically connected through the first substrate 201.

Referring to the second touch sensing part TSP2 illustrated in FIG. 4, the second inductor element LE2 may be spaced apart from the internal side surface of the second touch member TM2 by the predetermined distance D2 and may be mounted on one surface of the second substrate 202, and the second capacitor element CE2 may also be mounted on the one surface of the second substrate 202. The second bracket 302 may be attached to the other surface of the second substrate 202.

The second bracket 302 may be attached to the internal structure of the electronic device 10 to which the touch sensing device 50 is applied, or may be supported using a separate support member. The second bracket 302 is not limited to a specific structure, as long as the second inductor element LE2 and the second touch member TM2 maintain the predetermined distance D2.

Referring to the third touch sensing part TSP3 illustrated in FIG. 4, the third inductor element LE3 may be spaced apart from the internal side surface of the third touch member TM3 by the predetermined distance D3 and may be mounted on one surface of the third substrate 203, and the third capacitor element CE3 may also be mounted on the one surface of the third substrate 203. The third bracket 303 may be attached to the other surface of the third substrate 203.

The third bracket 303 may be attached to the internal structure of the electronic device 10 to which the touch sensing device 50 is applied, or may be supported using a separate support member. The third bracket 303 is not limited to a specific structure, as long as the third inductor element LE3 and the third touch member TM3 maintain a predetermined distance (e.g., D3, FIG. 4).

The first substrate 201, the second substrate 202, and the third substrate 203 may be formed independently of each other, or may be formed as a single substrate 200, as illustrated in FIG. 4, but are not limited to such configurations. For example, the substrate 200 may be made of FPCB, and in this case, the substrate 200 may include the first substrate 201, the second substrate 202, and the third substrate 203.

The first bracket 310, the second bracket 320, and the third bracket 330 may be formed independently of each other, or may be formed as a single bracket 300, as illustrated in FIG. 4, but are not limited to such configurations.

Referring to FIG. 4, the housing 500 may be made of a conductor such as metal. The first touch member TM1 to the third touch member TM3 may be integrally formed with the housing 500, and may be made of a conductive material such as metal that may be the same as that of the housing 500. Alternatively, the housing 500 may be made of a material other than metal.

Referring to the front view of the first to third inductor elements LE1, LE2, and LE3 of FIG. 4, in the A direction, for example, the first inductor element LE1 may correspond to a coil connected in a winding type, or may be a PCB coil pattern formed on a substrate. The coil or the PCB coil pattern may be electrically connected to the circuit unit CS and the first capacitor element CE1 through the substrate 200.

Similarly, the second inductor element LE2 and the third inductor element LE3 each may also correspond to a coil connected in a winding type, or may be a PCB coil pattern formed on a substrate. The coils or the PCB coil patterns may be electrically connected to the circuit unit CS, and the second capacitor element CE2 and the third capacitor element CE3, respectively, through the substrate 200.

The first, second, and third inductor elements LE1, LE2, and LE3 illustrated in FIG. 4 are merely illustrative, and the disclosure is not limited to these examples. In addition, the first touch sensing part TSP1, the third touch sensing part TSP2, and the third touch sensing part TSP3 illustrated in FIG. 4 are merely illustrative, and are not limited to the disclosed examples.

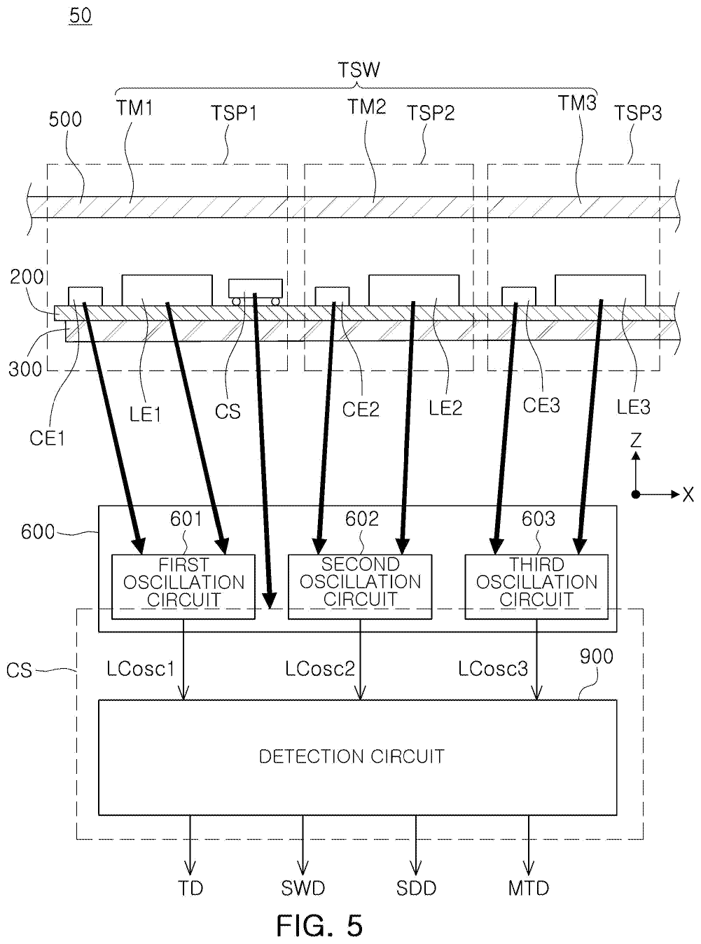

FIG. 5 is another example view of a cross-sectional structure (an X-Z cross-section) of one side surface of the electronic device 10.

Referring to FIG. 5, as described above, the electronic device 10 may include the housing 500, the touch switch unit TSW including the first touch member TM1, the second touch member TM2, and the third touch member TM3, and the touch sensing device 50.

The touch sensing device 50 may include the first inductor element LE1, the second inductor element LE2, the third inductor element LE3, an oscillation circuit 600, and a detection circuit 900.

For example, the first inductor element LE1 may be disposed inside the first touch member TM1, may oppose and may be spaced apart from the first touch member TM1 by the predetermined distance D1, and may have inductance changeable upon a force touch pressing the first touch member TM1 is performed. As another example, the first inductor element LE1 may be attached to the internal side surface of the first touch member TM1.

For example, the second inductor element LE2 may be disposed inside the second touch member TM2, may oppose and may be spaced apart from the second touch member TM2 by the predetermined distance D2, and may have inductance changeable upon a force touch pressing the second touch member TM2 is performed. As another example, the second inductor element LE2 may be attached to the internal side surface of the second touch member TM2.

For example, the third inductor element LE3 may be disposed inside the third touch member TM3, may oppose and may be spaced apart from the third touch member TM3 by the predetermined distance D3, and may have inductance changeable upon a force touch pressing the third touch member TM3 is performed. As another example, the third inductor element LE3 may be attached to the internal side surface of the third touch member TM3.

The oscillation circuit 600 may generate a first oscillation signal LCosc1 having a resonant frequency based on changeable inductance or changeable capacitance, a second oscillation signal LCosc2 having a resonant frequency based on changeable inductance or changeable capacitance, and a third oscillation signal LCosc3 having a resonant frequency based on changeable inductance or changeable capacitance.

The oscillation circuit 600 may include a first oscillation circuit 601, a second oscillation circuit 602, and a third oscillation circuit 603.

The first oscillation circuit 601 may include the first inductor element LE1, and the first capacitor element CE1 connected to the first inductor element LE1 in parallel, series, or series-parallel, to generate the first oscillation signal LCosc1.

The second oscillation circuit 602 may include the second inductor element LE2, and the second capacitor element CE2 connected to the second inductor element LE2 in parallel, series, or series-parallel, to generate the second oscillation signal LCosc2.

The third oscillation circuit 603 may include the third inductor element LE3, and the third capacitor element CE3 connected to the third inductor element LE3 in parallel, series, or series-parallel, to generate the third oscillation signal LCosc3.

The detection circuit 900 may be configured to analyze the first oscillation signal LCosc1, the second oscillation signal LCosc2, and the third oscillation signal LCosc3, to discern a type of a user's touch input. For example, the detection circuit 900 may compare at least one of the number of touch inputs, locations of touch inputs, a progress direction of the touch operation, and a touch strength level, with respect to a plurality of touch inputs, to discern a type of a touch operation applied by the user.

For example, the detection circuit 900 may convert the first oscillation signal LCosc1, the second oscillation signal LCosc2, and the third oscillation signal LCosc3 into a respective digital value thereof, to generate a first count value, a second count value, and a third count value, and may discern the type of the user's touch input, based on the first, second, and third count values.

In addition, since the first touch switch unit TSW-1 and the second touch switch unit TSW-2 may include the plurality of touch members TM1, TM2, and TM3, respectively, the detection circuit 900 may analyze at least one touch input applied to the plurality of touch members TM1, TM2, and TM3, to discern the type of the user's touch operation. In this case, the inductor element and the capacitor element may be provided as the plurality of inductor elements LE1, LE2, and LE3, and a plurality of capacitor elements CE1, CE2, and CE3, respectively, to correspond to the plurality of touch members TM1, TM2, and TM3, and the detection circuit 900 may analyze the user's touch input based on changeable inductance or capacitance values in each of the inductor elements LE1, LE2, and LE3 or capacitor elements CE1, CE2, and CE3.

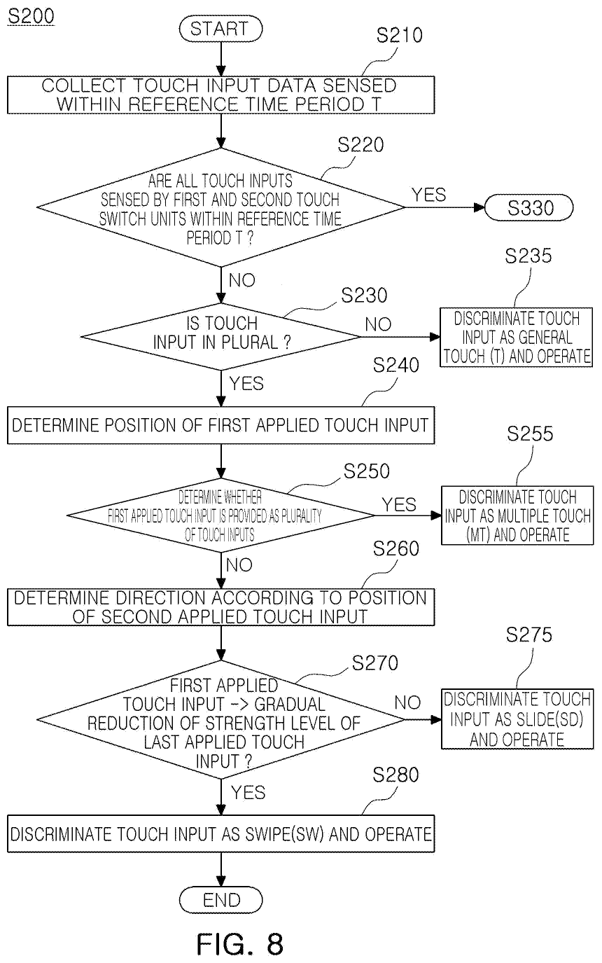

Details of analyzing the pattern of the user's touch input applied to the plurality of touch members TM1, TM2, and TM3 by the detection circuit 900 to discern the type of the touch input will be described later with reference to FIGS. 8 to 12.

Referring to FIGS. 4 and 5, in the first touch sensing part TSP1, the first touch member TM1 may be integrally formed with the housing 500, and may be made of, for example, aluminum or metal. The first inductor element LE1 may be disposed to be spaced apart from the first touch member TM1 by the first bracket 301 by the predetermined distance D1 (FIG. 4). A ferrite sheet (not illustrated) may be disposed on a lower surface of the first inductor element LE1, which may be not required. A shape of the first inductor element LE1 does not have to be a specific shape. Various patterns such as circles or squares are possible for the first inductor element LE1, and a PCB itself may be configured as a flexible PCB (FPCB). The first inductor element LE1 may also be replaced with a chip inductor.

The first substrate 201 may be an FPCB, and various types of PCBs, other than the FPCB, may be used. The first capacitor element CE1, such as MLCC for sensing, may be disposed on a mounting surface of the first substrate 201 (a surface of the first substrate 201 facing the internal side surface of the first touch member TM1) or on a surface opposing the mounting surface.

In addition, the first substrate 201 (e.g., FPCB), on which the first inductor element LE1 (e.g., PCB coil) and the first capacitor element CE1 (e.g., MLCC) are arranged, may be mounted on the first bracket 301 to be coupled to the housing 500, such that the predetermined distance D1 between the first inductor element LE1 and the first touch member TM1 may be maintained by the first bracket 301.

A force touch applied to the first touch member TM1 of the housing 500 may inwardly deform the first touch member TM1, and may change a distance between the first touch member TM1 and the first inductor element LE1, to change inductance. Therefore, a first touch input may be sensed by the oscillation circuit 600 and the detection circuit 900.

In addition, since a method in which a second touch input and a third touch input are respectively sensed in the second touch sensing part TSP2 and the third touch sensing part TSP3 is the same as that of the first touch sensing part TSP1 described above, overlapping descriptions with respect to the second and third touch sensing parts TSP2 and TSP3 are omitted herein.

Referring to FIGS. 4 and 5, when using a plurality of (e.g., three (3)) touch sensing structures according to an embodiment disclosed herein, as well as individual touch input, various types of operations according to the complex touch input may be distinguished and sensed.

In addition, the first oscillation circuit 601 may generate a first oscillation signal LCosc1 having a first resonant frequency that may be changeable in response to inductance of the first inductor element LE1 being changed upon a touch input through the first touch member TM1.

In addition, the second oscillation circuit 602 may generate a second oscillation signal LCosc2 having a second resonant frequency that may be changeable in response to inductance of the second inductor element LE2 being changed upon touch input through the second touch member TM2.

In addition, the third oscillation circuit 603 may generate a third oscillation signal LCosc3 having a third resonant frequency that may be changeable in response to inductance of the third inductor element LE3 being changed upon touch input through the third touch member TM3.

The detection circuit 900 may analyze strength and pattern of the user's touch input, based on an amount of change in the resonant frequency detected by the first to third oscillation circuits 601, 602, and 603, respectively. Based on the analyzed results, it is possible to discern a type of a corresponding touch input among various types of preset touch inputs.

For example, the various types of preset touch inputs may include a general touch input (TD), a swipe touch input (SWD), a slide touch input (SDD), and a multiple touch input (MTD). The detection circuit 900 may analyze a touch input within a reference time period t stored in advance as a bundle, to discern what type of touch input is applied by the user. Then, according to results discerned by the detection circuit 900, an operation of the corresponding electronic device 10 may be performed.

The first oscillation circuit 601 may include a first inductance circuit including inductance Lind of the first inductor element LE1 and a first capacitance circuit Cduct including capacitance Cext of the first inductor element LE1. In this case, when there is no touch input, inductance may be not changed.

Likewise, the second oscillation circuit 602 may include a second inductance circuit including inductance Lind of the second inductor element LE2 and a second capacitance circuit Cduct including capacitance Cext of the second inductor element LE2. In this case, when there is no touch input, inductance may be not changed.

In addition, the third oscillation circuit 603 may include a third inductance circuit including inductance Lind of the third inductor element LE3 and a third capacitance circuit Cduct including capacitance Cext of the third inductor element LE3. In this case, when there is no touch input, each inductance may be not changed.

For example, resonant frequencies fres of the first oscillation circuit 602, the second oscillation circuit 602, and the third oscillation circuit 603 may be expressed by Equation 1 below.

fres≈½π\sqrt{Lind*Cext} Equation 1

In Equation 1, is the same or similar, wherein ‘similar’ means that other values may be further included.

In addition, referring to FIG. 5, when a touch pressing a first touch member TM1 of the electronic device 10 is applied, an inductive sensing method may be applied, to detect a touch input.

For example, when a touch pressed by a conductor or a non-conductor is applied to the first touch member TM1, the first touch member TM1 may be first pressed and a distance between the first touch member TM1 and the inductor element LE1 may change while the first touch member TM1 is bent inwardly. When the distance between the first inductor element LE1 and the first touch member TM1, which may be a surrounding conductor, changes while a current flows through the first inductor element LE1, a magnitude of an eddy current may change, and inductance due to a change in the eddy current may decrease (Lind−ΔLind) to increase a first resonant frequency, to detect a first touch input.

In addition, a method in which the second touch member TM2 and the third touch member TM3 are pressed and detected as a second touch input and a third touch input, respectively, may be the same as that of the first touch member TM1 described above. Therefore, an overlapping description with respect to the second and third touch members TM2 and TM3 will be omitted.

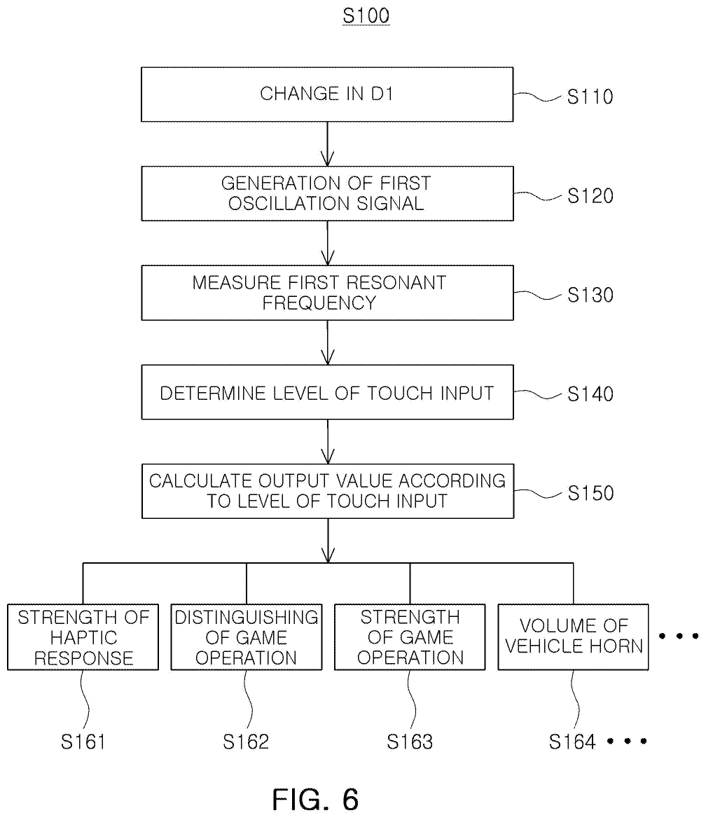

FIG. 6 is an example view of an operation description in which the electronic device 10 adjusts an output according to a strength level of a touch input. For example, FIG. 6 illustrates a touch sensing method S100 in which an operation output value of the electronic device 10 is calculated according to a strength level of a touch input, according to an embodiment.

For example, the first touch switch unit TSW-1 may be provided in the housing 500 of the electronic device 10 and, as illustrated in FIG. 4, the housing 500 and a first inductor element LE1 may be spaced from each other by the predetermined distance D1. In this case, when a user's touch input is applied to a first touch member TM1, the distance D1 between the housing 500 and the first inductor element LE1 may be changed in operation S110.

Then, as described above, in operation S120, a change in inductance of the first inductor element LE1 may occur, and the first oscillation signal LCosc1 may be generated in the first oscillation circuit 601 electrically connected to the first inductor element LE1. As an example, the first oscillation signal LCosc1 may have a first resonant frequency, and the first resonant frequency may represent a value changed by the change in inductance of the first inductor element LE1. In this case, an amount of change in the first resonant frequency may indicate a higher value, as strength of the user's touch input is higher.

Subsequently, in operation S130, the detection circuit 900 may receive the first oscillation signal LCosc1 from the first oscillation circuit 601, and may measure the first resonant frequency of the first oscillation signal. Then, in operation S140, the detection circuit 900 may determine a strength level of a corresponding touch input based on the measured first resonant frequency. In this case, the strength level of the touch input may be set and stored previously in the electronic device 10, and, for example, a detectable strength range may be divided into ten (10) levels and stored. When the user's touch input is applied, the detection circuit 900 may determine a strength level corresponding to a strength of corresponding touch input among previously stored strength levels.

When the strength level of the touch input is determined as described above, the detection circuit 900 may calculate an output value according to a level of the touch input in operation S150. For example, output values of various operations performed in the electronic device 10 may be calculated differently according to the strength level of the user's touch input.

In this case, as illustrated in FIG. 6, the output values of the electronic device 10 may refer to output values of various operations. For example, the detection circuit 900 may calculate at least one of a volume, vibration strength, an operation time period, the number of an operation, and an operation frequency in the electronic device 10 to match the level of the touch input.

For example, the electronic device 10 may be a mobile device, and, in this case, the output value calculated differently according to a level of the touch input may correspond to strength of a haptic response of the mobile device provided in operation S161. For example, a vibration strength of the mobile device may be adjusted according to the strength of the touch input that the user applies to the first touch switch unit TSW-1.

As another example, the electronic device 10 may be a device capable of executing game-related software (e.g., a game application, etc.). In this case, the output value that may be differently calculated according to a level of the touch input may correspond to distinguishing of the game operation provided in operation S162 or strength of the game operation provided in operation S163. For example, a type of a game operation to be performed by the device may be changed, or a time period, the number, a frequency, strength, or the like of game operations may be adjusted according to the strength of the touch input that the user applies to the first touch switch unit TSW-1.

As another example, the electronic device 10 may be a device that performs various electronic functions installed in a vehicle, and more specifically, may perform a function of providing a vehicle's horn sound according to a user's touch input. In this case, an output value calculated differently according to a level of the touch input may correspond to a volume of the vehicle's horn provided in operation S164. For example, a volume of the horn generated in the vehicle may be adjusted according to the strength of the touch input applied by the user to the touch switch unit TSW-1.

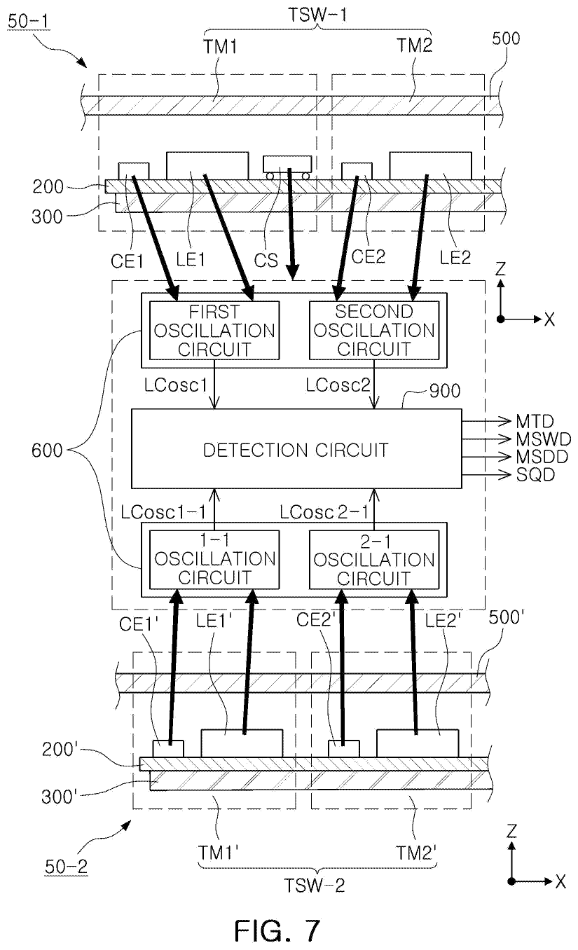

FIG. 7 is an example view illustrating respective cross-sectional structures (X-Z cross-sections) of both side surfaces of the electronic device 10, and connection structures of the electronic device 10.

Referring to FIG. 7, the touch sensing device 50 of the electronic device 10 may include a first touch sensing device 50-1 and a second touch sensing device 50-2. The first touch sensing device 50-1 and the second touch sensing device 50-2 may be operated separately, but, as illustrated in FIG. 7, may be operated in combination by sharing the detection circuit 900. Since the first and second touch sensing devices 50-1 and 50-2 are separately operated, and the elements described therein may overlap the contents described in FIG. 5, the discussion of FIG. 7 will mainly describe a method in which the first and second touch sensing devices 50-1 and 50-2 are operated in combination.

Referring to FIG. 7, the first touch switch unit TSW-1 and the second touch switch unit TSW-2 may be provided together in the housing 500. For example, the first touch switch unit TSW-1 and the second touch switch unit TSW-2 may be symmetrically provided on both side surfaces of the electronic device 10, respectively, and, to correspond thereto, the first touch sensing device 50-1 and the second touch sensing device 50-2 may be provided, respectively.

The first touch switch unit TSW-1, which is provided on one side of the electronic device 10, may include a first touch member TM1 and a second touch member TM2, and the second touch switch unit TSW-2, which is provided on the other side of the electronic device 10, may include a 1-1 touch member TM1′ and a 1-2 touch member TM2′. This example is merely illustrative, and the number of touch members provided in each of the first and second touch switch units TSW-1 and TSW-2 may vary.

Referring to FIG. 7, the first touch sensing device 50-1 may include the first inductor element LE1, the second inductor element LE2, the first capacitor element CE1, a second capacitor element CE2, the oscillation circuit 600, and the detection circuit 900.

For example, the first inductor element LE1 may be disposed inside the first touch member TM1, and may have inductance changeable when a force touch pressing the first touch member TM1 is performed. In addition, the second inductor element LE2 may be disposed inside the second touch member TM2, and may have inductance changeable when a force touch pressing the second touch member TM2 is performed.

Referring to FIG. 7, the second touch sensing device 50-2 may also have the same structure as the first touch sensing device 50-1. For example, the second touch sensing device 50-2 may include a 1-1 inductor element LE1′, a 2-1 inductor element LE2′, a 1-1 capacitor element CE1′, a 2-1 capacitor device CE2′, the oscillation circuit 600, and the detection circuit 900 may be included.

For example, the 1-1 inductor element LE1′ may be disposed inside the 1-1 touch member TM1′, and may have inductance changeable when a force touch pressing the 1-1 touch member TM1′ is performed. In addition, the 2-1 inductor element LE2′ may be disposed inside the 2-1 touch member TM2′, and may have inductance changeable when a force touch pressing the 2-1 touch member TM2′ is performed.

Referring to FIG. 7, the oscillation circuit 600 and the detection circuit 900 may be configured to be simultaneously included in the first touch sensing device 50-1 and the second touch sensing device 50-2. For example, the oscillation circuit 600 and the detection circuit 900 may be electrically connected to the first inductor element LE1, the second inductor element LE2, the first capacitor element CE1, the second capacitor element CE2, the 1-1 inductor element LE1′, the 2-1 inductor element LE2′, the 1-1 capacitor element CE1′, and the 2-1 capacitor element CE2′.

In this example, the oscillation circuit 600 may generate an oscillation signal having a resonant frequency based on changeable inductance or changeable capacitance. In addition, since the oscillation circuit 600 may be simultaneously included in the first touch sensing device 50-1 and the second touch sensing device 50-2, the oscillation circuit 600 may include a first oscillation circuit, a second oscillation circuit, a 1-1 oscillation circuit, and a 2-1 oscillation circuit.

The first oscillation circuit may include the first inductor element LE1, and the first capacitor element CE1 connected to the first inductor element LE1 in parallel, series, or series-parallel, to generate the first oscillation signal LCosc1.

The second oscillation circuit may include the second inductor element LE2, and the second capacitor element CE2 connected to the second inductor element LE2 in parallel, series, or series-parallel, to generate the second oscillation signal LCosc2.

The 1-1 oscillation circuit may include the 1-1 inductor element LE1′, and the 1-1 capacitor element CE1′ connected to the 1-1 inductor element LE1′ in parallel, series, or series-parallel, to generate a 1-1 oscillation signal LCosc1-1.

The 2-1 oscillation circuit may include the 2-1 inductor element LE2′, and the 2-1 capacitor element CE2′ connected to the second inductor element LE2′ in parallel, series, or series-parallel, to generate a 2-1 oscillation signal LCosc2-1.

The detection circuit 900 may be configured to collectively analyze the first oscillation signal LCosc1, the second oscillation signal LCosc2, the 1-1 oscillation signal LCosc1-1, and the 2-1 oscillation signal LCosc2-1, to discern a type of the user's touch input. For example, for example, the detection circuit 900 may compare any one or any combination of any two or more of the number of touch inputs, locations of touch inputs, a progress direction of the touch operation, and a touch strength level, with respect to the plurality of touch inputs applied to both side portions of the electronic device 10, to discern the type of the touch operation applied by the user.

Referring to FIG. 7, the first touch member TM1 may be integrally formed with the housing 500, and the first inductor element LE1 may be disposed to be spaced apart from the first touch member TM1 by the predetermined distance D1 (FIG. 4) by the first bracket 301. A shape of the first inductor element LE1 does not have to be a specific shape, and various patterns such as circles or squares are possible. For example, a PCB itself may be configured as a flexible PCB (FPCB). The first inductor element LE1 may also be replaced with a chip inductor.

In addition, the first substrate 201 (e.g., FPCB) on which the first inductor element LE1 (e.g., PCB coil) and the first capacitor element CE1 (e.g., MLCC) are arranged may be mounted on the first bracket 301 to be coupled to the housing 500, such that the predetermined distance D1 may be maintained between the first inductor element LE1 and the first touch member TM1 by the first bracket 301.

A force touch applied to the first touch member TM1 of the housing 500 may inwardly deform the first touch member TM1, and may change a distance between the first touch member TM1 and the first inductor element LE1, to change inductance. Therefore, a first touch input may be sensed by the oscillation circuit 600 and the detection circuit 900.

In addition, since a method in which each touch input is sensed by the second touch member TM2, the 1-1 touch member TM1′, and the 2-1 touch member TM2′ is the same as the method described above for the first touch member TM1, overlapping descriptions with respect to second touch member TM2, the 1-1 touch member TM1′, and the 2-1 touch member TM2′ will be omitted.

As illustrated in FIG. 7, when using a touch sensing structure having a plurality of touch switch units TSW-1 and TSW-2 and a plurality of (e.g., two (2), respectively) touch members TM1, TM2, TM1′ and TM2′, as well as individual touch input, various types of operations according to the complex touch input may be distinguished and sensed. For example, the number of cases related to the type of the user's touch input may increase.

In addition, the first oscillation circuit may generate the first oscillation signal LCosc1 having a first resonant frequency that may be changeable as inductance of the first inductor element LE1 is changed upon touch input through the first touch member TM1.

In addition, the second oscillation circuit may generate the second oscillation signal LCosc2 having a second resonant frequency that may be changeable as inductance of the second inductor element LE2 is changed upon touch input through the second touch member TM2.

In addition, the 1-1 oscillation circuit may generate the 1-1 oscillation signal LCosc1-1 having a 1-1 resonant frequency that may be changeable as inductance of the 1-1 inductor element LE1′ is changed upon touch input through the 1-1 touch member TM1′.

In addition, the 2-1 oscillation circuit may generate the 2-1 oscillation signal LCosc1-1 having a 2-1 resonant frequency that may be changeable as inductance of the 2-1 inductor element LE2′ is changed upon touch input through the 2-1 touch member TM2′.

The detection circuit 900 may analyze strength and pattern of the user's touch input, based on an amount of change in the resonant frequency detected by the first oscillation circuit, the second oscillation circuit, the 1-1 oscillation circuit, and the 2-1 oscillation circuit, respectively. Based on the analyzed results, it is possible to discern a type of a corresponding touch input among various types of preset touch inputs.

In this case, the various types of preset touch inputs applicable when the first touch switch unit TSW-1 and the second touch switch unit TSW-2 are used at the same time may include a multiple touch input and a sequential multiple touch input (MTD), a multiple swipe touch input (MSWD), a multiple slide touch input (MSDD), and a squeeze input (SQD). The detection circuit 900 may analyze a touch input within a reference time period t stored in advance as a bundle, to discern what type of touch input is applied by the user. Then, according to results discerned by the detection circuit 900, an operation of the corresponding electronic device 10 may be performed.

Descriptions of terms related to various types of touch input, such as the sequential multiple touch input (MTD), the multiple swipe touch input (MSWD), the multiple slide touch input (MSDD), and the squeeze input (SQD) will be described later with reference to FIGS. 8 to 12.

According to an embodiment, the first touch switch unit TSW-1 and the second touch switch unit TSW-2 may be symmetrically provided on both side surfaces of the electronic device 10, respectively. In addition, as described above, the first touch switch unit TSW-1 and the second touch switch unit TSW-2 may include a plurality of touch members TM1, TM2, TM1′ and TM2′, respectively, and may be configured to not form a dividing line or a dividing surface between the plurality of touch members TM1, TM2, TM1′ and TM2′.

As an example, when the electronic device 10 is a smartphone, integrated touch switch units (e.g., the first and second touch switch units TSW-1 and TSW-2) may be provided on both side surfaces of the smartphone, respectively. In addition, each of the touch switch units may include a plurality of touch members (e.g., the touch members TM1, TM2, TM1′ and TM2′).

In this example, a dividing line or a dividing surface structurally forming a blocking unit may not be formed between the plurality of touch members TM1, TM2, TM1′ and TM2′ included in the first touch switch unit TSW-1 and the second touch switch unit TSW-2. For example, a dividing line or a dividing surface may not be formed in an exterior of the electronic device 10, and a dividing line or a dividing surface functionally blocking transmission of force may not be formed between each touch sensing device 50-1 and 50-2 disposed therein.

Therefore, the user may easily perform touch operations such as slide, swipe, and squeeze without heterogeneous inconvenience, and precise sensing with regard to the user's touch operation may be allowed.

Additionally, the touch switch unit may be provided in at least a portion of a dashboard including a steering wheel and a center fascia of a vehicle. In addition, the electronic device 10 may be a device capable of performing various electronic functions operated inside and outside the vehicle. As an example, the electronic device 10 may be a device configured to generate a horn sound according to a user's touch input of the vehicle.

The electronic device 10 may determine a level of a touch input according to strength of the touch input applied to the touch switch unit TSW-1 or TSW-2, and may differently calculate a function output value (e.g., a volume of the horn or the like) operated in the vehicle according to the determined level of the touch input. For example, when a user applies a touch input having a high strength level to the touch switch unit, a relatively large volume of vehicle horn may be output, and when a user applies a touch input having a low strength level, a relatively small volume of vehicle horn may be output.

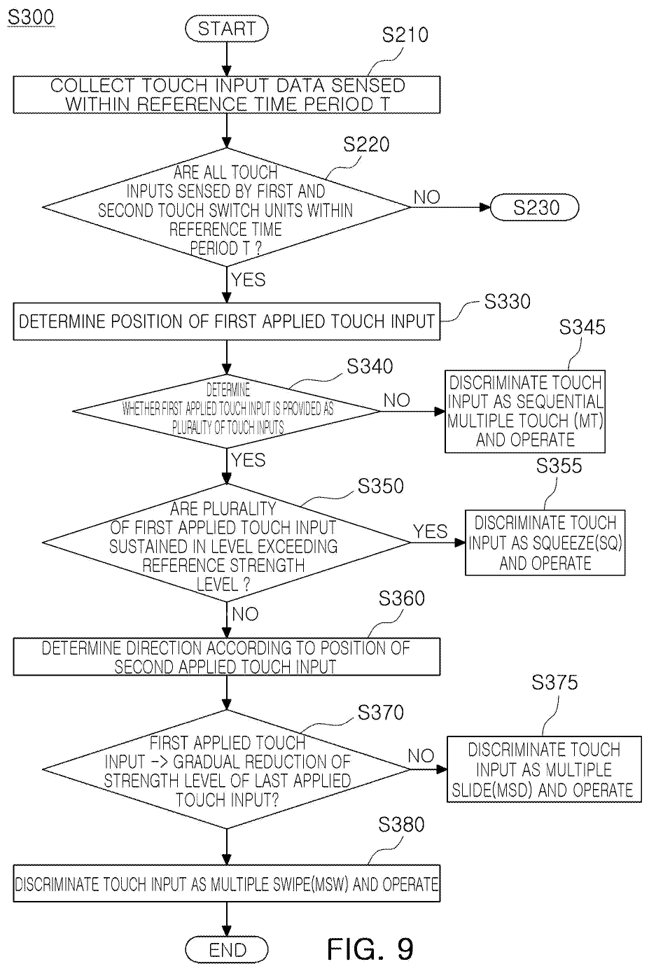

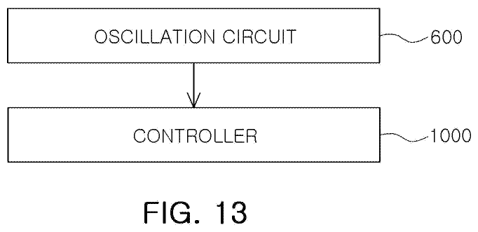

FIG. 8 is an example view illustrating an operation of discerning and sensing a type of a touch input, when the touch input is applied to a touch switch unit (e.g., the first touch switch unit TSW-1 or the second touch switch unit TSW-2) on one side surface of the electronic device 10, according to an embodiment. For example, the operations in FIGS. 8 and 9 may correspond to, for example, the detection circuit 900 included in the touch sensing device 50. This is merely an example, and each of the operations may be performed by a separate computing device or a control device (e.g., a processor) installed in the electronic device 10. For example, as illustrated in FIG. 13, a controller 1000 may be used instead of the detection circuit 900, and may be in communication with the oscillation circuit 600. However, for convenience, and not by limitation, the following description, as an example, each of the operations of the touch sensing method will be described as being performed by the detection circuit 900.

Referring to FIG. 8, a touch sensing method S200, according to an embodiment, may include discerning a type of a touch input applied to a touch switch unit (e.g., the first touch switch unit TSW-1 or the second touch switch unit TSW-2) provided on one side of the electronic device 10.

Referring to FIG. 8, first, the detection circuit 900 may collect touch input data sensed within a reference time period t, in operation S210. For example, when a touch applied by a user corresponds to a single touch input, which may be independent, it is not necessary to consider the reference time period t. When the user intends to apply a single touch input through a plurality of touches, the reference time period t needs to be considered. Therefore, the reference time period t may be set and stored in advance in an electronic device 10, and the detection circuit 900 may collectively consider the touch input sensed during the reference time period t to discern a type of the user's touch input.

For example, when a single touch input is sensed in a touch switch unit (e.g., the first touch switch unit TSW-1 or the second touch switch unit TSW-2), the detection circuit 900 may record whether there is an additional touch input that is additionally sensed for the reference time period t, after the touch input. In this case, the reference time period t may be set and stored as a time period determined to intentionally and collectively apply the plurality of touches with a single command by the user.

For example, when the reference time period t is set to 2 seconds, after the user applies a single touch input, it may be difficult for the detection circuit 900 to distinguish an operation of applying another touch input, which is independent from the single touch input. When the reference time period t is set to 0.1 second, the detection circuit 900 may incorrectly determine an operation of applying a plurality of touches to collectively apply a single touch input by the user, as separate touch inputs. Therefore, the reference time period t may be set and stored as a time period determined to intentionally and collectively apply the plurality of touches with a single command by the user, and may be set to about 0.5 seconds, as an example.

The reference time period t, which is preset and stored, may be reset according to a user characteristic of the corresponding electronic device 10, as records of a user's touch inputs are accumulated.

Subsequently, referring to FIG. 8, the detection circuit 900 may analyze the touch input data sensed within the reference time period t, in operation S 220. For example, in operation S220, the detection circuit 900 may determine whether all of the touch inputs are sensed by each of the first touch switch unit TSW-1 and the second touch switch unit TSW-2 within the reference time period t. For example, it may be determined whether at least one touch input sensed during the reference time period t includes all of the touch input applied to the first touch switch unit TSW-1 and the touch input applied to the second touch switch unit TSW-2.

In this case, when it is determined that not all of the touch inputs are applied to each of the touch switch units TSW-1 and TSW-2 (for example, when it is determined that the touch input is applied to only a single touch switch unit TSW-1 or TSW-2), the detection circuit 900 may discern a type of a touch operation as one of a general touch or a multiple touch, for example, as one of a multiple touch, a slide touch, or a swipe touch with respect to a single touch switch unit TSW-1 or TSW-2. Then, the touch sensing method by the detection circuit 900 may continue to proceed to operation S230.

In this case, when it is determined that all of the touch inputs are applied to each of the touch switch units TSW-1 and TSW-2, the detection circuit 900 may discern a type of a touch operation applied by the user as one of a multiple touch, a sequential multiple touch, a multiple swipe touch, a multiple slide touch, and a squeeze. As described above, when there is a touch operation according to at least one touch input applied to the plurality of touch switch units TSW-1 and TSW-2, the touch sensing method may proceed to operation S330 illustrated in FIG. 9. Operation S330 will be described later with reference to FIG. 9.

Referring to FIG. 8, when it is determined that at least one touch input sensed within the reference time period t is not applied to each of the first and second touch switch units TSW-1 and TSW-2, the detection circuit 900 may then determine, in operation S230, whether a touch input sensed within the reference time period t is provided as plurality of touch inputs.

In this case, when there is only a single touch input sensed within the reference time period t, the detection circuit 900 may discern the touch input as a general touch (T) in operation S235, and the electronic device 10 may typically perform an operation corresponding to a case in which a single touch is applied.

When there are a plurality of touch inputs sensed within the reference time period t, it may be determined that a plurality of touch inputs are applied in the first touch switch unit TSW-1 or the second touch switch unit TSW-1. In this case, in operation S240, the detection circuit 900 may determine a position of a first applied touch input among the plurality of touch inputs, and may record the determined position of the first applied touch input.

Subsequently, in operation S250, the detection circuit 900 may determine whether the first applied touch input is provided as a plurality of touch inputs. For example, the detection circuit 900 may determine whether a plurality of touch inputs are applied simultaneously or within a time period that may be recognized as simultaneous (e.g., 0.05 seconds).

As a result of the determination, when it is determined that the first applied touch input is provided as a plurality of touch inputs, the detection circuit 900 may discern the corresponding touch input as a general multiple touch (MT) in operation S255, and the electronic device 10 may perform an operation corresponding to a case in which a touch input is simultaneously applied to at least two (2) touch members. For reference, the general multiple touch (MT), described herein, refers to an operation touching a plurality of touch members included in a single touch switch unit among the first touch switch unit TSW-1 and the second touch switch unit TSW-2 at the same time. For example, the general multiple touch (MT) may be a concept that may be distinguished from the sequential multiple touch (MT) to which touch inputs are simultaneously applied to the touch switch units TSW-1 and TSW-2 located on both side surfaces, and will be described later.

When it is determined that the first applied touch input is not provided as a plurality of touch inputs, the detection circuit 900 may determine a progress direction of an operation according to a position of a second applied touch input, in operation S260. In addition, the detection circuit 900 may compare a position of a first applied touch input, recorded previously, and a position of a second applied touch input and, may determine the progress direction of the touch operation (in a direction toward the position of the second applied touch input from the position of the first applied touch input).

Subsequently, in operation S270 the detection circuit 900 may respectively determine the strength levels of the plurality of pieces of touch input data, and may determine whether the determined strength levels of each touch input sequentially decrease. For example, in order to determine whether a strength level sequentially decreases, a strength level of a first applied touch input and a strength level of a last applied touch input may be compared to each other. Alternatively, strength levels of the plurality of touch inputs including the first applied touch input and the last applied touch input may be compared with each other in time sequence.

When it is determined, in the manner described above, that the strength levels of the plurality of pieces of touch input data are not sequentially reduced, but are maintained or increased, the detection circuit 900 may discern a type of a touch operation applied by the user as a slide touch (SD), and may perform an operation of the electronic device 10 corresponding thereto, in operation S275.

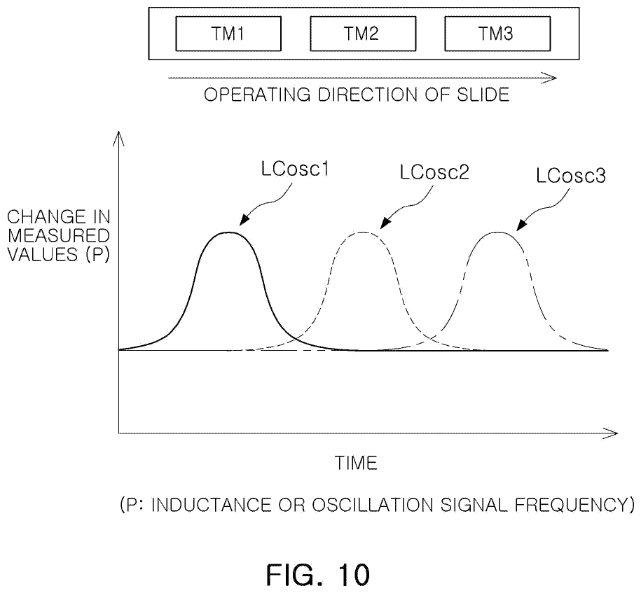

In this case, the slide touch (SD) refers to a touch that the user applies the touch while moving a finger in a longitudinal direction of the touch switch unit TSW-1 or TSW-2, and pushes or drags the touch while maintaining the same force. A detection mode of the slide touch SD will be described with reference to FIG. 10.

FIG. 10 is an example view schematically illustrating a change in frequency or inductance of the oscillation signals LCosc1, LCosc2, and LCosc3 generated in the first, second, and third of touch members TM1, TM2, and TM3 by a slide touch input, according to an embodiment. For reference, an x-axis of the graphs illustrated in FIGS. 10 to 12 herein represents to a time period, and a y-axis represents to an amount of change in inductance or resonant frequency of an oscillation signal generated in an inductor element. In this case, the time period on the x-axis does not refer to a specific time, but is only an example of expressing a relationship between time periods. In addition, an amount of change in inductance or an amount of change in resonant frequency of the oscillation signal on the y-axis may be described as a change in measured values P by unifying terms for convenience of explanation, but for the same situation, each value has the same sign (+ or −) that is not changed. For example, when a touch input is applied, an amount of change in inductance among the measured values P may have a negative value, and an amount of change in resonant frequency of the oscillation signal may have a positive value, or vice-versa.

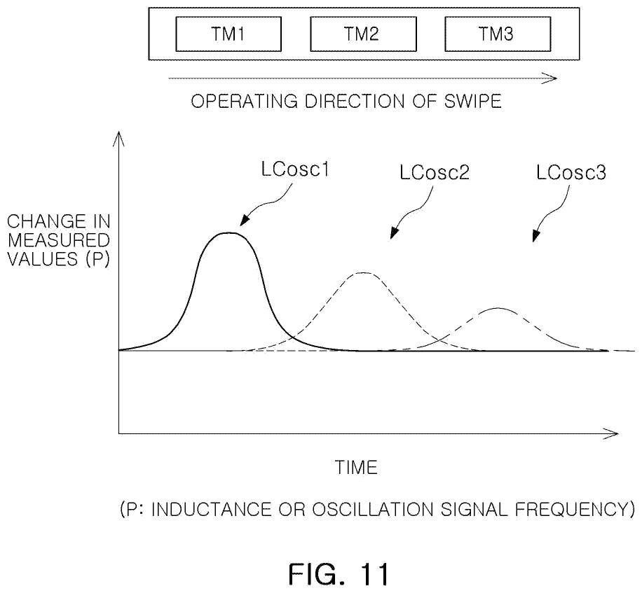

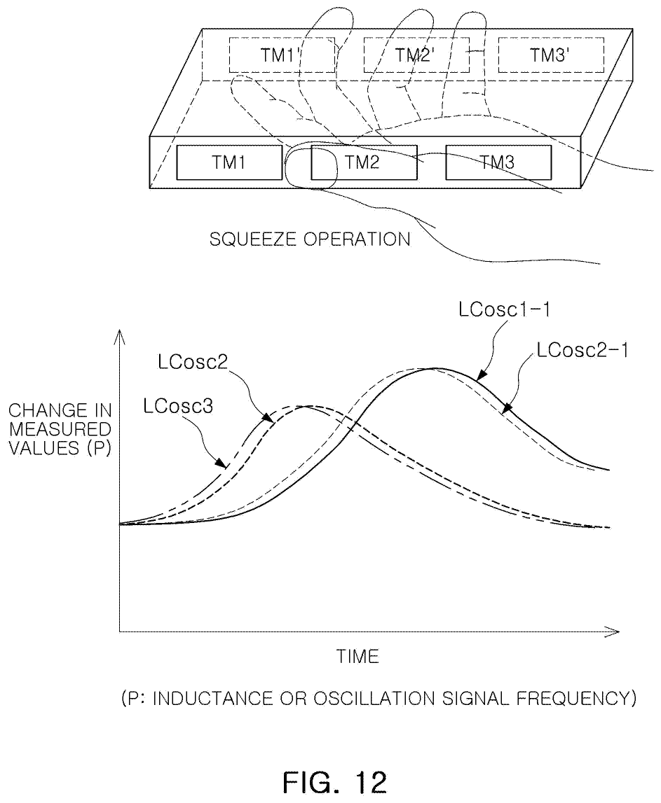

In addition, in FIGS. 11 and 12, y values for a change in measured values P (e.g., an amount of change in inductance or an amount of change in resonant frequency of the oscillation signal) for each of the graph lines corresponding to each of the oscillation signals may be illustrated to have different peaks. This merely exemplifies that amounts of change in measured values P of touch inputs applied by the first, second, and third touch members TM1, TM2, TM3, or the like may be different from one another. For example, the peaks expressed in FIGS. 10 to 12 do not have any correlation with each other, and a difference in peaks between the plurality of graph lines illustrated in each of the drawings does not indicate a relative size ratio.

Referring to FIGS. 8 and 10 together, for example, the first touch switch unit TSW-1 may include the first, second, and third touch members TM1, TM2, and TM3, and the oscillation signals LCosc1, LCosc2, and LCosc3 may be respectively generated by a touch input applied to each of the first, second, and third touch members TM1, TM2, and TM3. In this example, resonant frequencies of the oscillation signals LCosc1, LCosc2, and LCosc3 may be determined according to an amount of change in inductance changeable in each of the first, second, and third inductor elements LE1, LE2, and LE3 as described above. For example, as a strong touch input is applied, a relatively large amount of change in inductance of the inductor element LE1, LE2, or LE3 may be measured, and a relatively large amount of change in resonant frequency of the oscillation signal LCosc1, LCosc2, or LCosc3 may be measured.

Continuing with reference to FIG. 10, since a touch input by a slide operation may be to apply a touch by an operation of applying the same force to of the first, second, and third touch members TM1, TM2, and TM3 by a user to drag or push the first, second, and third of touch members TM1, TM2, and TM3, the first, second, and third oscillation signals LCosc1, LCosc2, and LCosc3 respectively generated by the touch input applied to the first, second, and third touch members TM1, TM2, and TM3 may have almost the same amount of change in inductance or almost the same amount of change in resonant frequency. Therefore, the graph of FIG. 10 illustrates a state in which a change in the measured values P of the first oscillation signal LCosc1, the second oscillation signal LCosc2, and the third oscillation signal LCosc3 are almost the same.

In addition, referring to FIG. 10, it can be seen that an operation direction of a slide touch SD according to this graph passes through the second touch member TM2 from the first touch member TM1, and then passes toward the third touch member TM3. In this case, different commands may be set in the electronic device 10, according to an operation direction of a slide touch SD or a swipe touch SW. Therefore, an operation direction of the touch input may be changed to apply a touch, to perform different operations in the electronic device 10.

When it is determined that strength levels of plurality of pieces of touch input data are sequentially decreased, the detection circuit 900 may discern a type of a touch operation applied by a user as a swipe touch (SW), and the electronic device 10 corresponding thereto may be performed.

In this case, the swipe touch (SW) refers to a touch that the user applies while moving a finger in a longitudinal direction of the touch switch unit, but does not press while maintaining the same force, but presses with and then raises an end of the finger up like a bounce while moving in a progress direction. A detection mode of the swipe touch SW will be described with reference FIG. 11.

FIG. 11 is an example view schematically illustrating a change in frequency or inductance of the oscillation signals LCosc1, LCosc2, and LCosc3 generated in of the first, second, and third touch members TM1, TM2, and TM3 by a swipe touch input.

Referring to FIGS. 8 and 11 together, for example, the first touch switch unit TSW-1 may include of the first, second, and third touch members TM1, TM2, and TM3, and the oscillation signals LCosc1, LCosc2, and LCosc3 may be respectively generated by a touch input applied to each of the first, second, and third touch members TM1, TM2, and TM3. In this case, resonant frequencies of the first, second, and third oscillation signals LCosc1, LCosc2, and LCosc3 may be determined according to an amount of change in inductance changeable in each of the inductor elements LE1, LE2, and LE3, as described above. For example, as a strong touch input is applied, a relatively large amount of change in resonant frequency of the oscillation signal LCosc1, LCosc2, or LCosc3 may be measured.

Continuing with reference to FIG. 11, a touch input by a swipe operation may be applied by a touch operation of pressing with and then raising an end of the finger up like a bounce while moving in a progress direction with regard to of the first, second, and third touch members TM1, TM2, and TM3 by a user. In the touch input by the swipe operation, the first, second, and third oscillation signals LCosc1, LCosc2, or LCosc3 generated by the touch input applied to the first, second, and third touch members TM1, TM2, and TM3, respectively, may not have the same amount of change in inductance or the same amount of change in resonant frequency. For example, according to the swipe operation, the first applied touch input corresponds to an input having a relatively high strength level that sequentially decreases over time. Therefore, the graph of FIG. 11 illustrates a state in which an amount of change in the measured values P of the first oscillation signal LCosc1, the second oscillation signal LCosc2, and the third oscillation signal LCosc3 gradually decreases. In addition, referring to FIG. 11, it can be seen that an operation direction of a swipe touch SW according to the graph passes through the second touch member TM2 from the first touch member TM1, and then passes toward the third touch member TM3.

FIG. 9 is an example view illustrating an operation of discerning and sensing a type of a touch input, when the touch input is applied to the touch switch units TSW-1 and TSW-2 on both sides of the electronic device 10, according to an embodiment.

Referring to FIG. 9, a touch sensing method S300, according to an embodiment, may include discerning a type of a touch input applied to the first and second touch switch units TSW-1 and TSW-2 provided on both side surfaces of the electronic device 10. For example, FIG. 9 illustrates a touch sensing method when a touch input is collectively detected in a plurality of touch switch units, unlike FIG. 8.

As described above with reference to FIG. 8, the detection circuit 900 may analyze the touch input data sensed within the reference time period t. For example, in operation S220, the detection circuit 900 may determine whether all of the touch inputs are sensed by the first touch switch unit TSW-1 and the second touch switch unit TSW-2 within the reference time period t. In this case, when it is determined that all of the touch inputs are not applied to each of the touch switch units TSW-1 and TSW-2, the touch sensing method by the detection circuit 900 may continue to proceed to operation S230 of FIG. 8 described above.

In this example, when it is determined to include all of the touch inputs are applied to each of the touch switch units, the touch sensing method may continue to proceed to operation S330 illustrated in FIG. 9.

For reference, in this example, the detection circuit 900 does not need to determine whether there are a plurality of touch inputs sensed within the reference time period t, unlike in FIG. 8. For example, since this operation is an operation after determining whether all of the touch inputs are sensed by the first touch switch unit TSW-1 and the second touch switch unit TSW-2, a touch sensing method may be always performed, after it being determined that a plurality of touch inputs have been sensed.

Continuing with reference to FIG. 9, in operation S330, the detection circuit 900 may determine a position of the first applied touch input among the plurality of touch inputs, and may record the position of the first applied touch input. Subsequently, in operation S340, the detection circuit 900 may determine whether the first applied touch input is provided as a plurality of touch inputs. For example, the detection circuit 900 may determine whether a plurality of touch inputs are applied simultaneously or within a time period that may be recognized as simultaneous (e.g., 0.05 seconds).

As a result of the determination, when it is determined that the first applied touch input is not provided as a plurality of touch inputs, the detection circuit 900 may discern the touch input as a sequential multiple touch (MT) in operation S345, and the electronic device 10 may perform an operation corresponding to a case in which touch inputs are sequentially applied at time intervals with respect to the touch switch units TSW-1 and TSW-2 on both sides of the electronic device 10. The sequential multiple touch (MT), described herein may be an operation in which a plurality of touches are applied at relatively short intervals to the first touch switch unit TSW-1 and the second touch switch unit TSW-2. For example, the sequential multiple touch (MT) may be distinguished from the general multiple touch (MT) in which a plurality of touch inputs are applied to a single touch switch unit described above.

As a result of the determination in operation S345, when the first applied touch input is provided as a plurality of touch inputs, the detection circuit 900 may determine whether the plurality of first applied touch inputs are sustainably detected in a level on or above a reference strength level, in operation S350. For example, a minimum time period as the reference strength level and a reference for determining whether the reference strength level is sustained in the plurality of first applied touch inputs may be preset and stored in the electronic device 10, respectively.

As a result of the determining of the strength level of the first applied touch input by the detection circuit 900, when the touch input is sustained for a minimum time period (e.g., 1 second, etc.) while having strength at or above a predetermined reference strength level, respectively, the type of the touch operation may be discerned as a squeeze (SQ).

The squeeze (SQ) may be an operation in which the user grips the electronic device 10 using a palm and a finger, and applies force. A detection mode of the squeeze SQ will be described with reference to FIG. 12.

FIG. 12 is an example view schematically illustrating a change in frequency or inductance of oscillation signals LCosc1, LCosc2, LCosc3, LCosc1-1, LCosc2-1, or LCosc3-1 generated in the first, second, third, of touch members by a squeeze touch input.

Referring to FIGS. 9 and 12 together, for example, the first touch switch unit TSW-1 may the first, second, and third touch members TM1, TM2, and TM3, and the second touch switch unit TSW-2 may include of the 1-1, 2-1, and 3-1 touch members TM1′, TM2′, and TM3′. For example, the second, third, 1-1, and 2-1 oscillation signals LCosc2, LCosc3, LCosc1-1, and LCosc2-1 may be respectively generated by a touch input applied to each of the second, third, 1-1, and 2-1 touch members TM2, TM3, TM1′ and TM2′. In this case, resonant frequencies of the second, third, 1-1, and 2-1 oscillation signals LCosc2, LCosc3, LCosc1-1, and LCosc2-1 may be determined according to an amount of change in inductance changeable in each of the inductor elements LE2, LE3, LE1′, LE2′, as described above. For example, as a strong touch input is applied, a relatively large amount of change in resonant frequency of the oscillation signal LCosc2, LCosc3, LCosc1-1, or LCosc2-1 may be measured.

Continuing with reference to FIG. 12, the touch input by the squeeze operation maybe a touch input by a user gripping the electronic device 10 to simultaneously press the first and second touch switch units TSW-1 and TSW-2 on both sides with a plurality of touch members (e.g., the second, third, 1-1, and 2-1 touch members TM2, TM3, TM1′ and TM2′). Therefore, according to various factors such as a size of a user hand, and a width and a thickness of the electronic device 10, a type and the number of touch members to which the touch input is applied may vary according to the squeeze operation of the user.

When considering a change in inductance corresponding to the squeeze operation, a criterion for discerning the squeeze operation needs to be simply set, as compared to other touch operations. For example, for example, as illustrated in FIG. 9, without specifying a touch member, a plurality of first applied touch inputs may be set to be discerned, based on whether or not the plurality of first applied touch inputs are sustained at a level on or above the reference strength level.

As an example, referring to FIG. 12, according to the squeeze operation of the user, it can be seen that touch inputs are applied to the second touch member TM2 and the third touch member TM3 of the first touch switch unit TSW-1, and the 1-1 touch member TM1′ and the 2-1 touch member TM2′ of the second touch switch unit TSW-2, respectively. As described above, when a plurality of oscillation signals may be generated in a plurality of touch members simultaneously (LCosc2 and LCosc3) or within a short time period enough to be regarded as being simultaneous (LCosc1-1 and LCosc2-1), and an amount of change in the resonant frequency of each of the oscillation signals LCosc2, LCosc3, LCosc1-1, and LCosc2-1 (or an amount of change in inductance generated in each of the inductor elements LE2, LE3, LE1′, and LE2′) is sustained while having a large value, the detection circuit 900 may discern the corresponding touch operation as squeeze.

Referring to FIG. 9, the detection circuit 900 may then determine a progress direction of an operation according to a position of a second applied touch input, in operation S360. In addition, the detection circuit 900 may compare a position of a first applied touch input, recorded previously, and a position of a second applied touch input and, may determine the progress direction of the touch operation (in a direction toward the position of the second applied touch input from the position of the first applied touch input).

Subsequently, in operation S370, the detection circuit 900 may respectively determine the strength levels of the plurality of pieces of touch input data, and may determine whether the determined strength levels of each touch input sequentially decrease. For example, in order to determine whether a strength level sequentially decreases, a strength level of a first applied touch input and a strength level of a last applied touch input may be compared to each other. Alternatively, strength levels of the plurality of touch inputs including the first applied touch input and the last applied touch input may be compared with each other in time sequence.

When it is determined, in the manner described above, that the strength levels of the plurality of pieces of touch input data are not sequentially reduced, but are maintained or increased, the detection circuit 900 may discern a type of a touch operation applied by the user as a multiple slide touch (MSD), and an operation of the electronic device 10 corresponding to the multiple slide touch (MSD) may be performed, in operation S375.

In this case, the multiple slide touch (MSD) refers to an operation in which a user applies a touch while simultaneously moving a finger in the longitudinal direction with respect to the first and second touch switch units TSW-1 and TSW-2 on both sides of the electronic device 10, but applies a slide touch while maintaining the same force. In this case, for example, the user may perform the slide operation with respect to the first touch switch unit TSW-1 in a direction from an upper portion to a lower portion of the electronic device 10, and the second touch switch unit TSW-2 in a direction from a lower portion to an upper portion of the electronic device 10. Further, the user may perform the slide operation in the same direction with respect to the first touch switch unit TSW-1 and the second touch switch unit TSW-2. For example, depending on directions of the slide operations applied to both sides, the electronic device 10 may be configured to recognize separate touch input operations, and perform different operations.

When it is determined that the strength levels of the plurality of pieces of touch input data sequentially decrease, the detection circuit 900 may discern a type of a touch operation applied by the user as a multiple swipe touch (MSW), and an operation of the electronic device 10 corresponding to the multiple swipe touch (MSW) may be performed.

In this case, the multiple swipe touch (MSW) may be an operation in which a user applies a touch while simultaneously moving a finger in the longitudinal direction with respect to the touch switch units of both sides, but applies a swipe touch pressing with and then raising an end of the finger up like a bounce while moving in a progress direction. In this case, the user may apply swipe touch inputs having different operating directions to the first and second touch switch units TSW-1 and TSW-2 on both sides of the electronic device 10, as in the multiple slide touch (MSD). For example, depending on directions of the swipe operations applied to both sides of the electronic device 10, the electronic device 10 may be configured to recognize separate touch input operations, and perform different operations.

According to embodiments disclosed herein, a touch sensing method and an electronic device including a touch sensing device may distinguish and sense user touch inputs as various types of touch inputs according to strength and pattern of a touch.

In addition, in a touch sensing method and an electronic device according disclosed herein, a plurality of touch members may be disposed on a touch switch unit without distinguishing a region of the touch members, such that a user may easily perform a touch operation such as slide, swipe, and squeeze. In addition, it is possible to precisely sense the user's touch operation.

In addition, in a touch sensing method and an electronic device according to the disclosure herein, touch switch units may be provided on both sides of the electronic device, and the touch switch units may be separately used such that separate touch inputs respectively applied to the touch switch units may be sensed, or collectively used such that touch inputs collectively applied to the touch switch units may be sensed. Therefore, the number of cases related to a type of touch input may increase.

The controller 1000 in FIG. 13 that performs the operations described in this application is implemented by hardware components configured to perform the operations described in this application that are performed by the hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-13 that perform the operations described in this application are performed by computing hardware, for example, by one or more processors or computers, implemented as described above executing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions in the specification, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access memory (RAM), flash memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A touch sensing method, comprising:
generating respective oscillation signals having a resonant frequency, the respective oscillation signals being changeable according to a plurality of touch inputs applied to a first touch switch unit and a second touch switch unit, formed in a housing of an electronic device;
analyzing the applied plurality of touch inputs, based on a change in the resonant frequency of the generated oscillation signals; and
discerning and sensing a type of a touch operation according to a pattern of the plurality of touch inputs, based on results of the analyzing of the applied plurality of touch inputs.

2. The touch sensing method according to claim 1, further comprising:
determining a touch input level according to a strength of the plurality of touch inputs, based on the analyzed results; and
calculating an operation output value of the electronic device according to the determined touch input level.

3. The touch sensing method according to claim 2, wherein the calculating of the operation output value of the electronic device according to the determined touch input level comprises: calculating either one of a volume, a vibration strength, an operation time period, a number of operations, or an operation frequency of the electronic device to match the touch input level.

4. The touch sensing method according to claim 1, wherein the discerning and sensing of the type of the touch operation comprises comparing any one or any combination of any two or more of a number of touch inputs, locations of touch inputs, a progress direction of the touch operation, and a touch strength level, with respect to the plurality of touch inputs, to discern the type of the touch operation.

5. The touch sensing method according to claim 1, wherein the analyzing of the applied plurality of touch inputs comprises collecting and analyzing only a plurality of pieces of touch input data applied within a reference time period previously stored in the electronic device.

6. The touch sensing method according to claim 5, wherein the discerning and sensing of the type of the touch operation comprises:
determining whether the collected plurality of pieces of touch input data corresponds to a touch input applied to the first touch switch unit and a touch input applied to the second touch switch unit; and
discerning the type of the touch operation as any one of a multiple touch, a sequential multiple touch, a multiple slide touch, a multiple swipe touch, and a squeeze, in response to a result of the determining whether the collected plurality of pieces of touch input data corresponds to the touch input applied to the first touch switch unit and the touch input applied to the second touch switch unit being that the collected plurality of pieces of touch input data corresponds to the touch input applied to both the first touch switch unit and the touch input applied to the second touch switch unit.

7. The touch sensing method according to claim 6, further comprising: discerning the type of the touch operation as any one of a multiple touch, a slide touch, and a swipe touch with respect to a single touch switch unit among the first and second touch switch units, in response to the result of the determining whether the collected plurality of pieces of touch input data corresponds to the touch input applied to the first touch switch unit and the touch input applied to the second touch switch unit being that the collected plurality of pieces of touch input data does not correspond to the touch input applied to both the first touch switch unit and the touch input applied to the second touch switch unit.

8. The touch sensing method according to claim 6, further comprising:
determining the number of data of touch inputs first applied, among the collected plurality of pieces of touch input data; and
further discerning the type of the touch operation as the sequential multiple touch, in response to:
the result of the determining whether the collected plurality of pieces of touch input data corresponds to the touch input applied to the first touch switch unit and the touch input applied to the second touch switch unit being that the collected plurality of pieces of touch input data corresponds to the touch input applied to both the first touch switch unit and the touch input applied to the second touch switch unit; and
the number of data of touch inputs first applied being one.

9. The touch sensing method according to claim 8, further comprising:
determining whether each of the plurality of touch inputs first applied is sustained for a minimum time period while having a strength level greater than or equal to a predetermined reference strength level; and
further discerning the type of the touch operation as the squeeze, in response to:
the result of the determining whether the collected plurality of pieces of touch input data corresponds to the touch input applied to the first touch switch unit and the touch input applied to the second touch switch unit being that the collected plurality of pieces of touch input data corresponds to the touch input applied to both the first touch switch unit and the touch input applied to the second touch switch unit;
the number of data of the touch inputs first applied being a plural number; and
a result of the determining of whether each of the plurality of touch inputs first applied is sustained for the minimum time period while having the strength level greater than or equal to the predetermined reference strength level is that the plurality of touch inputs first applied are sustained for the minimum time period while having the strength level greater than or equal to the predetermined reference strength level.

10. The touch sensing method according to claim 5, wherein the discerning and sensing of the type of the touch operation comprises:
comparing a position of a first applied touch input, among the collected plurality of pieces of touch input data, with a position of a second applied touch input, among the collected plurality of pieces of touch input data, to determine a progress direction of the touch operation.

11. The touch sensing method according to claim 5, wherein the discerning and sensing of the type of the touch operation comprises:
determining strength levels of the collected plurality of pieces of touch input data, respectively; and
discerning the type of the touch operation as a swipe touch, in response to a result of the determining of the strength levels of the collected plurality of pieces of touch input data being that the strength levels of the collected plurality of pieces of touch input data sequentially decrease.

12. The touch sensing method according to claim 11, further comprising:
discerning the type of the touch operation as a slide touch, in response to a result of the determining of the strength levels of the collected plurality of pieces of touch input data being that the strength levels of the collected plurality of pieces of touch input data are maintained constant or increase.

13. An electronic device, comprising:
a touch switch unit formed in a housing; and
a touch sensing device configured to sense a touch input applied to the touch switch unit,
wherein the touch switch unit comprises:
a first touch switch unit disposed on one side surface of the electronic device; and
a second touch switch unit disposed on another side surface of the electronic device.

14. The electronic device according to claim 13, wherein the touch sensing device comprises:
an oscillation circuit configured to generate respective oscillation signals corresponding to the first touch switch unit and the second touch switch unit, each of the respective oscillation signals having a resonant frequency that is changeable according to a plurality of touch inputs, constituting the touch input, applied to the first touch switch unit and the second touch switch unit; and
a detection circuit configured to discern a type of a touch operation according to a pattern of the plurality of touch inputs, based on a change in resonant frequency of the generated respective oscillation signals.

15. The electronic device according to claim 14, wherein the detection circuit is further configured to determine a touch input level according to a strength of the plurality of touch inputs, and calculate an operation output value of the electronic device according to the determined touch input level.

16. The electronic device according to claim 14, wherein the detection circuit is further configured to compare any one or any combination of any two or more of a number of touch inputs, locations of touch inputs, a progress direction of the touch operation, and a touch strength level, with respect to the plurality of touch inputs, to discern the type of the touch operation.

17. The electronic device according to claim 14, wherein the touch sensing device further comprises:
an inductor element configured to exhibit a change in inductance as the touch input is applied to the touch switch unit; and
a capacitor element electrically connected to the inductor element, and configured to exhibit a change in capacitance as the touch input is applied to the touch switch unit,
wherein the oscillation circuit is electrically connected to the inductor element and the capacitor element, to generate the respective oscillation signals.

18. The electronic device according to claim 14, wherein each of the first touch switch unit and the second touch switch unit comprises a plurality of touch members,
wherein the touch sensing device further comprises:
a plurality of inductor elements corresponding to the plurality of touch members and configured to exhibit a change in inductance as the plurality of touch inputs are applied to the first touch switch unit and the second touch switch unit; and
a plurality of capacitor elements respectively electrically connected to the plurality of inductor elements and configured to exhibit a change in capacitance as the plurality of touch inputs are applied to the first touch switch unit and the second touch switch unit, and
wherein the detection circuit is further configured to analyze only a plurality of pieces of touch input data applied within a reference time period previously stored, among the plurality of touch inputs, to discern the type of the touch operation.

19. The electronic device according to claim 13, wherein the first touch switch unit and the second touch switch unit are symmetrically disposed on the one side surface of the electronic device and the other side surface of the electronic device,
wherein each of the first touch switch unit and the second touch switch unit comprises a plurality of touch members, and
wherein a dividing line or a dividing surface is not formed between the plurality of touch members.

20. The electronic device according to claim 13, wherein the touch switch unit is disposed in a region of a dashboard of a vehicle including a steering wheel and a center fascia, and
wherein the electronic device is configured to determine a touch input level according to a strength of the touch input applied to the touch switch unit, and calculate an operating output value implemented in the vehicle differently according to the determined touch input level.

21. An electronic device, comprising:
a first group of touch members disposed on one surface of the electronic device;
a second group of touch members disposed on another surface of the electronic device;
an oscillation circuit configured to generate a first group of oscillation signals corresponding to the first group of touch members, and a second group of oscillation signals corresponding to the second group of touch members; and
a controller configured to determine a type of a touch operation corresponding to a pattern of a plurality of touch inputs applied to a plurality touch members among the first group of touch members and the second group of touch members, based on a detected change in resonant frequency of one or more oscillation signals among the first group of oscillation signals and the second group of oscillation signals.

22. The electronic device of claim 21, wherein the controller is further configured to determine an operation output value of the electronic device based on a strength of the plurality of touch inputs.

23. The electronic device of claim 21, wherein the controller is further configured to compare any one or any combination of any two or more of a number of the plurality of touch inputs, locations of the plurality of touch inputs, a progress direction of the plurality of touch inputs, and a touch strength level of the plurality of touch inputs, to determine the type of the touch operation.

24. The electronic device of claim 21, wherein the controller is further configured to determine the type of the touch operation based on whether a strength of the plurality of touch inputs is above a reference strength level for a predetermined amount of time.
